(19) United States
(12) Patent Application Publication
(10) Pub. No.: US 2007/0025403 A1
(43) Pub. Date: Feb. 1, 2007

(54) Semiconductor wafer and method of manufacturing semiconductor device

(76) Inventors: Hajime Nagano, Yokohama-Shi (JP); Yoshihiko Saito, Yokosuka-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/493,511

(22) Filed: Jul. 27, 2006

(30) Foreign Application Priority Data
Jul. 29, 2005 (JP) 2005-221162

(51) Int. Cl. H01S 5/00

(52) U.S. Cl. 372/45.011

(57) ABSTRACT

A graded SiGe buffer layer 12 and a SiGe buffer layer 13 are formed on a Si substrate 11. A strained Si layer 14 having a critical film thickness or less is formed to decrease a stress applied to an interface between the strained Si layer 14 and the SiGe buffer layer 13, thereby obtaining a strained Si layer 14, in which a crystal defect density is low. Furthermore, the surface of the strained Si layer 14 is covered by a SiGe cap layer 21, which has a lattice constant greater than Si, thereby preventing the strained Si layer 14 from disappearing due to the sacrifice oxidation performed in the later steps, and enabling a gate oxide layer to be formed thereon. Thus, it is possible to obtain a high-quality strained Si wafer.

### CROSS-REFERENCE TO RELATED APPLICATION

This application is based upon and claims the benefit of priority from prior Japanese Patent Application No. 2005-221162, filed on Jul. 29, 2005, the entire contents of which are incorporated herein by reference.

### BACKGROUND OF THE INVENTION

1. Field of the Invention

The present invention relates to a semiconductor wafer and a method of manufacturing a semiconductor device.

2. Background Art

When a strained Si layer is used to form a channel portion of a transistor, the mobility of electrons is improved due to the stress in the strained Si layer. Accordingly, it is possible to increase the operation speed of elements with the design rule being the same as the conventional one.

A wafer (semiconductor substrate) having such a strain is manufactured by, for example, forming a graded SiGe buffer layer, in which the Ge concentration is gradually increased, on a Si substrate, forming a SiGe buffer layer, in which the Ge concentration is constant, on the graded SiGe buffer layer, and then forming a strained Si layer on the SiGe buffer layer.

However, when a thick strained Si layer is formed by the aforementioned method, a defect is caused in the strained Si layer. If the strained Si layer is thinned in order to avoid such a problem, the strained Si layer disappears before the formation of a gate oxide layer, as disclosed in, for example, Japanese Patent Publication No. 19888/1995.

As described above, conventionally there is no semiconductor wafer or method of manufacturing a semiconductor device that a defect density in a strained Si layer is sufficiently low whereas a strained Si layer exists or remains before the formation of a gate oxide layer.

### SUMMARY OF THE INVENTION

A semiconductor wafer according to a first aspect of the embodiment of the present invention, a semiconductor wafer comprising:

a semiconductor substrate;

a first semiconductor layer serving as a buffer layer formed on the semiconductor substrate, a lattice constant of the first semiconductor layer being different from a lattice constant of the semiconductor substrate;

a second semiconductor layer serving as a strained semiconductor layer formed on the first semiconductor layer; and

a third semiconductor layer serving as a cap layer formed on the second semiconductor layer.

A method of manufacturing a semiconductor device according to a second aspect of the embodiment of the present invention, a method of manufacturing a semiconductor device comprising:

forming a first semiconductor layer on the semiconductor substrate, the first semiconductor layer serving as a buffer layer, a lattice constant of the first semiconductor layer being different from a lattice constant of the semiconductor substrate;

forming a second semiconductor layer serving as a strained semiconductor layer on the first semiconductor layer;

re-growing the second semiconductor layer to compensate for a thickness of the second semiconductor layer, which has been decreased during a previous manufacturing process;

forming an insulating film on the second semiconductor; and

forming a semiconductor element on the insulating film.

A method of manufacturing a semiconductor device according to a third aspect of the embodiment of the present invention, a method of manufacturing a semiconductor device comprising:

forming a first semiconductor layer on the semiconductor substrate, the first semiconductor layer serving as a buffer layer, and a lattice constant of the first semiconductor layer being different from a lattice constant of the semiconductor substrate;

forming a second semiconductor layer serving as a strained semiconductor layer on the first semiconductor layer;

forming a third semiconductor layer serving as a cap layer on the second semiconductor layer, removing at least part of the third semiconductor layer;

forming an insulating film on the second semiconductor; and

forming a semiconductor element on the insulating film.

### BRIEF DESCRIPTION OF THE DRAWINGS

FIG. 1(a) is a sectional view of a semiconductor wafer according to a first embodiment of the present invention, and FIG. 1(b) is an enlarged sectional view of a part of the portion A in FIG. 1(a).

FIG. 2 is a sectional view for explaining a part of the post-processes of a method of manufacturing a semiconductor wafer according to the first embodiment of the present invention.

FIG. 3 is a sectional view for explaining a part of the post-processes of a method of manufacturing a semiconductor wafer according to the first embodiment of the present invention.

FIG. 4 is a sectional view for explaining a part of the post-processes of a method of manufacturing a semiconductor wafer according to the first embodiment of the present invention.

FIG. 5 is a sectional view showing a part of the processes of a method of manufacturing a semiconductor wafer according to a second embodiment of the present invention.

FIG. 6(a) is a sectional view showing a part of the processes of a method of manufacturing a semiconductor wafer according to the second embodiment of the present invention and FIG. 6(b) is an enlarged sectional view of a part of the portion A of FIG. 6(a).

FIG. 7(a) is a sectional view showing a part of the processes of a method of manufacturing a semiconductor wafer according to the second embodiment of the present invention and FIG. 7(b) is an enlarged sectional view of a part of the portion A of FIG. 7(a).

FIG. 8(a) is a sectional view of a semiconductor wafer, which the present inventors know, and FIG. 8(b) is an enlarged sectional view of a part of the portion A of FIG. 8(a).

FIG. 9 is a characteristic diagram showing the relationship between the film thickness and the number of defects in the strained Si layer 14.

FIG. 10 is a sectional view for explaining a part of the post-processes of a method of manufacturing a semiconductor wafer which the present inventors know.

FIG. 11 is a sectional view for explaining a part of the post-processes of the method of manufacturing a semiconductor wafer which the present inventors know.

FIG. 12 is a sectional view for explaining a part of the post-processes of the method of manufacturing a semiconductor wafer which the present inventors know.

### DESCRIPTION OF THE EMBODIMENTS

Before the embodiments of the present invention are described, a method of manufacturing a semiconductor wafer known by the present inventors will be described.

As mentioned previously, when a strained Si layer is used to form a channel portion of a transistor, the mobility of electrons can be improved due to the stress in the strained Si layer. Accordingly, it is possible to increase the operation speed of elements with the design rule being the same as the conventional one.

An example of a wafer having a starin is shown in a sectional view of FIG. 8(a), which is formed by forming a graded SiGe buffer layer 12, in which the Ge concentration is gradually increased, on a Si substrate 11, forming a SiGe buffer layer 13, in which the Ge concentration is constant, on the graded SiGe buffer layer 12, and then forming a strained Si layer 14 on the SiGe buffer layer.

FIG. 8(b) is an enlarged view of a part of the portion A in FIG. 8(a) in the case where a strained Si layer having a thickness of 15 nm is formed. In FIG. 8(b), a part of a thickness of SiGe buffer layer 13 is only shown. As shown in FIG. 8(b), in the strained Si layer 14 manufactured by the aforementioned method, 10E5/cm² of penetrating dislocation 102 exists, and also misfit dislocation 101 exists. Accordingly, it is not possible to manufacture a semiconductor element having a quality deserving mass production.

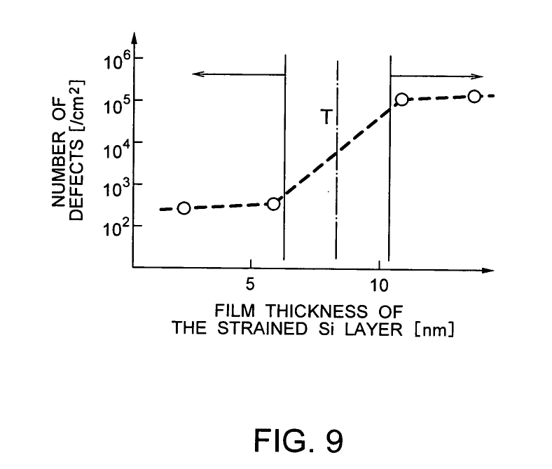

FIG. 9 is a characteristic diagram showing the relationship between the film thickness of the strained Si layer and the number of the penetrating dislocations. As is clear from FIG. 9, the density of the penetrating dislocation 102 increases depending on the film thickness of the strained Si layer 14. In particular, when the film thickness of the strained Si layer 14 exceeds the critical film thickness T, the penetrating dislocation density rapidly increases.

Accordingly, in order to decrease the density of the penetrating dislocation 102, the film thickness of the strained Si layer 14 should be decreased to the critical film thickness T or less.

On the other hand, if ion implantation or heat treatment is performed on the strained Si layer 14 on the Si wafer during the process of manufacturing a semiconductor element, the film thickness of the strained Si layer 14 is decreased due to the sacrifice oxidation etc. As a result, the strained Si layer may disappear due to the diffusion of Ge from the SiGe buffer layer 13.

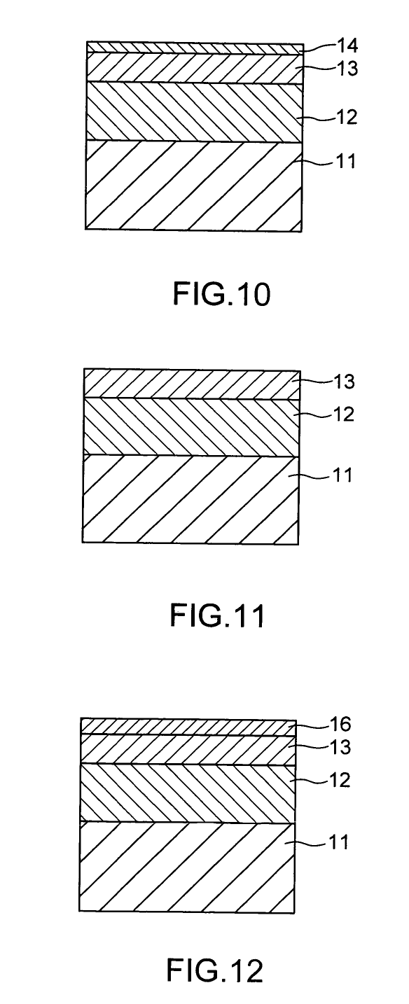

Thus, as shown in FIG. 10, if the film thickness of the strained Si layer 14 is set to be the critical film thickness T or less before starting the formation of the semiconductor element, the thickness of the strained Si layer 14 is gradually decreased as the process proceeds due to sacrifice oxidation etc. during the process. As a result, it is likely that no strained Si layer 14 is left at the time the gate oxide layer is formed, as shown in FIG. 11. In such a case, a gate oxide layer 16 is directly formed on a SiGe buffer layer 13 as in the case mentioned in FIG. 12.

Thus, in order to leave the strained Si layer 14 at the time the gate oxide layer is formed, it is necessary to form a strained Si layer having a film thickness more than the amount lost before the formation of the gate oxide layer, considering the semiconductor manufacturing process. If the initial film thickness of the strained Si layer should be thicker than the critical film thickness T, it is not possible to form a strained Si layer having a high quality, which does not have many crystal defects. Accordingly, it is not possible to form a semiconductor element having a high quality.

Hereinafter, embodiments of the present invention will be described with reference to the accompanying drawings.

### First Embodiment

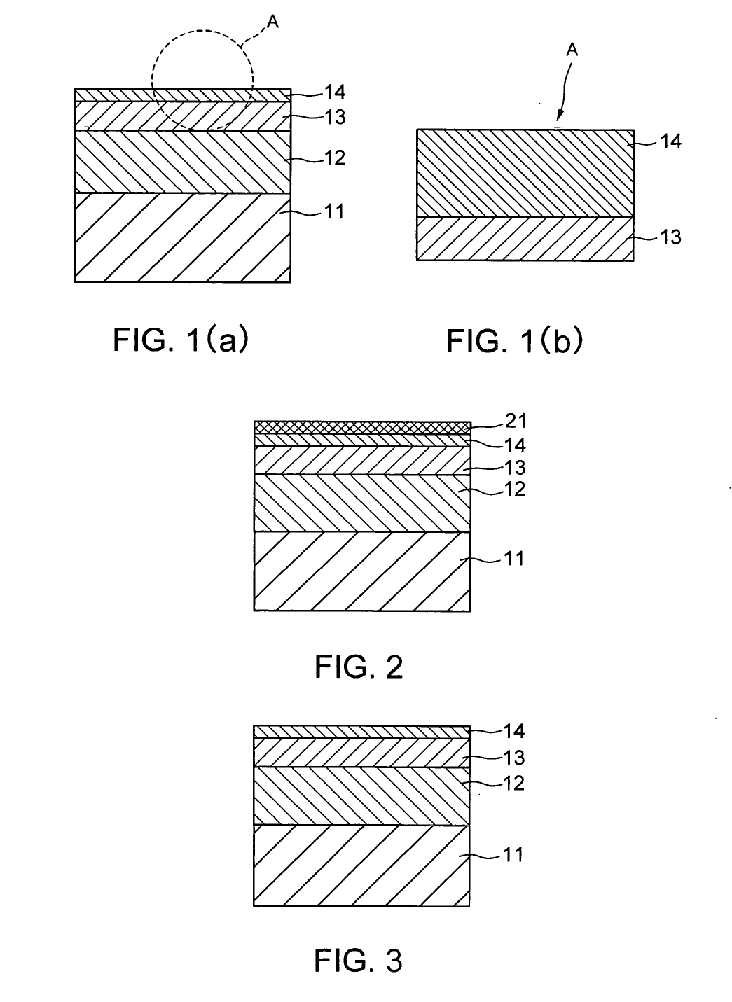

FIG. 1(a) is a sectional view showing the structure of a semiconductor wafer according to a first embodiment of the present invention. As can be understood from FIG. 1, a graded SiGe buffer layer 12, in which the Ge concentration is gradually increased, is formed on a Si substrate 11, a SiGe buffer layer 13 having a Ge concentration of 30% is formed, and then a strained Si layer 14 having a thickness of 5 nm is formed. That is to say, the film thickness of the strained Si layer 14 is thinner than the critical film thickness T.

Therefore, as shown in FIG. 1(b), which is a sectional view obtained by enlarging a part of the portion A in FIG. 1(a), no misfit dislocation exists at the interface between the strained Si layer 14 and the SiGe buffer layer 13, and no penetrating dislocation exists in the Si layer 14. In FIG. 1(b), a part of a thickness of SiGe buffer layer 13 is only shown.

Subsequently, as shown in FIG. 2, a SiGe cap layer 21 is formed on the strained Si layer 14. The film thickness of the SiGe cap layer 21 is set to be substantially the same as the thickness of the surface layer, which would disappear due to sacrifice oxidation etc. before the formation of the gate oxide layer during the process of manufacturing the semiconductor element.

As a result, as shown in FIG. 3, the SiGe cap layer 21 disappears due to the sacrifice oxidation during the process. Thus, it is possible to leave the strained Si layer 14 having a desired thickness before the formation of the gate oxide layer.

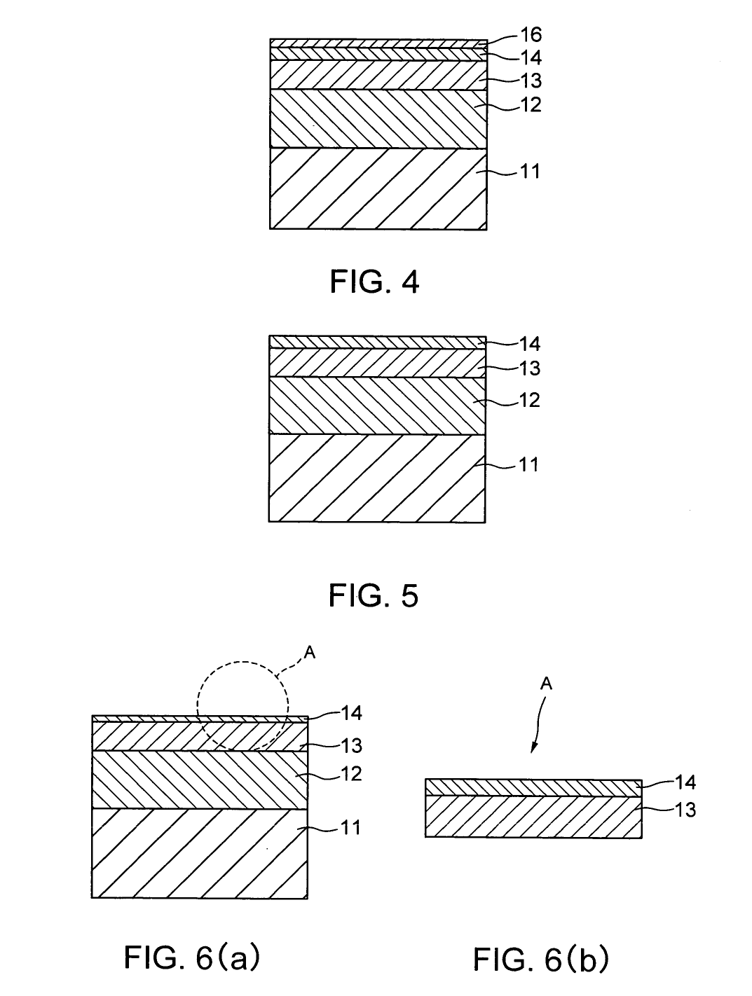

Thereafter, as shown in FIG. 4, a gate oxide layer 16 is formed on the strained Si layer 14.

Next, a manufacturing method according to the first embodiment will be described in more detail.

First, as shown in FIG. 1(a), a semiconductor wafer including a strained Si layer 14 is manufactured. The film thickness of the strained Si layer 14 is set to be thinner than the critical film thickness T.

Thereafter, as shown in FIG. 2, a SiGe cap layer 21 is formed on the strained Si layer 14 by supplying SiH₄ at 0.1 to 0.2 slm, supplying GeH₄ at 0.02 to 0.05 slm, and supplying H₂ at 10 to 15 slm under such conditions as the substrate temperature of 600 to 650° C. and the pressure of 5 to 10 Torr.

It is desirable that the Ge concentration of the SiGe cap layer 21 be more than 0 and 5 or less percent. If the Ge concentration is more than 5%, a problem, such as a failure to form a thermally-oxidized film thereon, may arise. The film thickness of the SiGe cap layer is 5 to 30 nm.

Although SiH₄ can be replaced with SiH₂Cl₂ and GeH₄ can be replaced with GeCl₄, it is desirable that the Ge concentration and the film thickness of the SiGe cap layer 21 are within the ranges mentioned before.

The defect density in the strained Si layer 14 of the semiconductor wafer obtained by the aforementioned process is decreased by about three orders of magnitude from the defect density in the case where the film thickness of the strained Si layer 14 is more than the critical film thickness T. In addition, due to the existence of the SiGe cap layer 21, the strained Si layer 14 is sufficiently left at the time of the formation of the gate oxide layer as shown in FIG. 3. Accordingly, it is possible to form a gate oxide layer on the strained Si layer 14.

As described above, it is possible to solve the problems such as penetrating dislocation and misfit dislocation by setting the film thickness of the strained Si layer 14 to be the critical film thickness T or less. Furthermore, it is possible to prevent the disappearance of the strained Si layer 14 caused by sacrifice oxidation etc. by forming the SiGe cap layer 21 on the strained Si layer 14. As a result, it is possible to obtain a strained Si layer 14 having a high quality, and to form a semiconductor element having a high quality thereon.

Although the case where the SiGe cap layer 21 is formed on the strained Si layer 14 is described as an example of this embodiment, it is possible to obtain the same effect by forming a semiconductor layer having a greater lattice constant than the strained Si layer. Moreover, it is possible to obtain the same effect by doping stibium, etc. at a high concentration to the strained Si layer 14.

### Second Embodiment

FIG. 5 is a sectional view showing a semiconductor wafer according to a second embodiment of the present invention.

As can be understood from FIG. 5, a graded SiGe buffer layer 12, in which the Ge concentration is gradually increased, is formed on a Si substrate 11, a SiGe buffer layer 13 having a Ge concentration of 30% is formed, and then a strained Si layer 14 having a thickness of 5 nm is formed thereon. In this case, the film thickness of the strained Si layer 14 is set to be thinner than the critical film thickness T.

Therefore, no misfit dislocation is caused at the interface between the Si layer 14 and the SiGe buffer layer 13, and no penetrating dislocation is caused within the strained Si layer 14.

If ion implantation or heat treatment is performed on the strained Si layer 14 in order to manufacture a semiconductor element, the strained Si layer disappears due to the Ge diffusion from the SiGe buffer layer 13, as described above.

If, during the process of manufacturing a semiconductor element, a Si layer is re-grown on the strained Si layer 14 in a range not to exceed the critical film thickness T before the strained Si layer 14 disappears due to sacrifice oxidation etc., and then the process is restarted, it is possible to leave the strained Si layer having a desired film thickness before the formation of a gate oxide layer.

Specifically, first a strained semiconductor wafer including a strained Si layer 14 having a film thickness of 6 nm is formed by a known method, as shown in FIG. 4.

Thereafter, ion implantation is performed in order to form semiconductor elements such as transistors on the strained semiconductor wafer. Specifically, the strained Si semiconductor wafer is heated at a temperature of 800° C. under the oxygen atmosphere to form a thermally oxidized film having a thickness of 4 nm. Then, P or B ions are injected at an acceleration voltage of 1 MeV. After the ion implantation, the strained Si semiconductor wafer is dissolved into a solution containing hydrofluoric acid to remove the thermally oxidized film.

As a result, as shown in FIG. 6(a) and FIG. 6(b), which is a sectional view obtained by enlarging a part of the portion A of FIG. 6(a), the strained Si layer 14 is thinned due to sacrifice oxidation etc. In FIG. 6(b), a part of a thickness of SiGe buffer layer 13 is only shown. As a result of experimental measurement, the film thickness of the strained Si layer 14 was 2 nm.

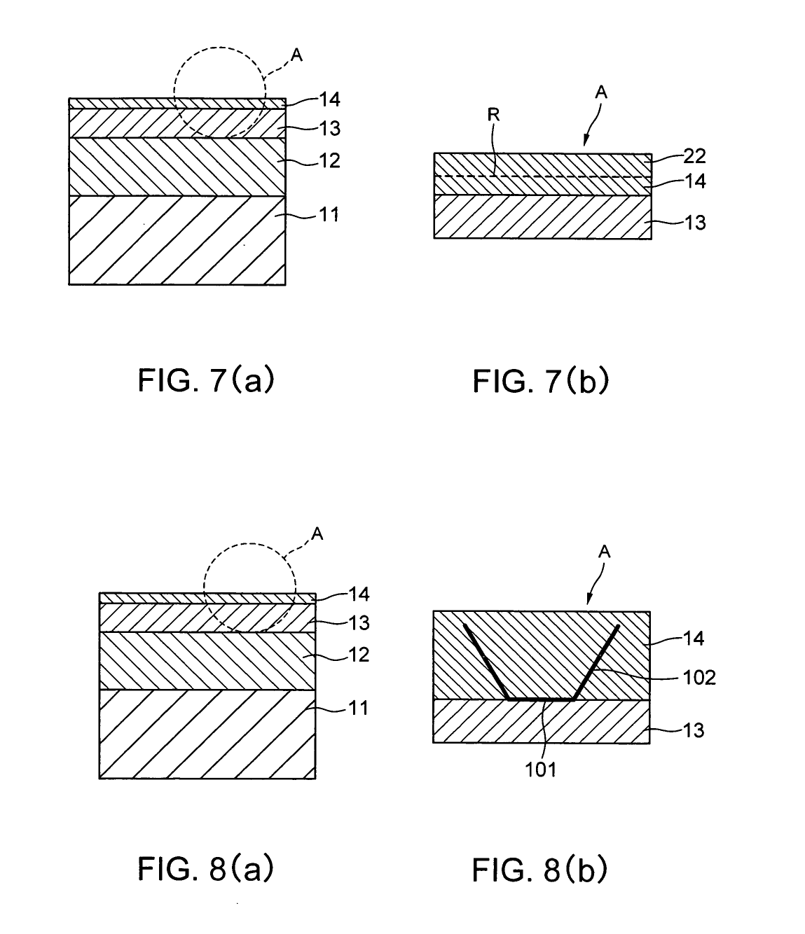

Next, the strained Si wafer is inserted into a low-pressure CVD apparatus, in which SiH₄ is supplied at 0.1 to 0.2 slm and 10-15 liters of hydrogen is supplied to the surface of the strained Si layer at a substrate temperature of 600 to 650° C., thereby forming a Si regrowth layer 22 having a thickness of about 4 nm on the regrowth interface R of the Si layer, as shown in FIG. 7(a) and FIG. 7(b), which is a sectional view obtained by enlarging the portion A of FIG. 7(a).

As a result, the sum of the thicknesses of the Si regrowth layer 22 and the strained Si layer 14 becomes 6 nm. Since this film thickness does not exceed the critical film thickness T, no misfit dislocation or penetrating dislocation is caused at the layer interface between the strained Si layer 14 and the SiGe buffer layer 13.

Subsequently, the strained Si wafer is inserted into a thermal oxidation furnace to stat a step of forming a gate oxide layer of a transistor.

As a result, the defect density in the strained Si layer 14 is decreased by about three orders of magnitude from the defect density in the case where the film thickness of the strained Si layer 14 is more than the critical film thickness T. Since it is possible to form a gate oxide layer on the strained Si layer 14, it is possible to obtain a high-quality strained Si layer in a strained semiconductor wafer.

As described above, according to the embodiments of the present invention, it is possible to form a strained Si layer in which the crystal defect density is low by forming a SiGe buffer layer on a Si (silicon) substrate, and forming a strained Si layer having a thickness less than the critical film thickness on the SiGe buffer layer to decrease the stress applied to an interface between the strained Si layer and the SiGe buffer layer.

Moreover, it is possible to prevent the loss of the strained Si layer due to sacrifice oxidation performed later by capping or covering the surface of the strained Si layer with a semiconductor layer having a higher lattice constant than a Si layer, e.g., a SiGe layer. Thus, it is possible to manufacture a semiconductor element using a strained semiconductor layer having a high quality, in which the defect density is low.

In addition, even if the strained Si layer is thinned due to sacrifice oxidation during the process of manufacturing a semiconductor device on the semiconductor wafer, it is possible to manufacture a semiconductor device having a high quality, which is suitable for forming a gate oxide layer in a later step, by epitaxial growing a Si layer during the process of manufacturing a semiconductor device to re-grow a strained Si layer having a high quality to have a thickness of a critical film thickness or less.

In each embodiment of the present invention, a graded SiGe buffer layer is formed on a substrate, and a SiGe buffer layer having a constant Ge concentration is formed thereon. However, the present invention is not limited to such an example, but it is possible that a BOX layer is formed on a substrate, a SiGe buffer layer having a constant Ge concentration is formed thereon, and a strained Si layer is formed thereon.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

1. A semiconductor wafer comprising:
A a semiconductor substrate;
a first semiconductor layer serving as a buffer layer formed on the semiconductor substrate, a lattice constant of the first semiconductor layer being different from a lattice constant of the semiconductor substrate;
a second semiconductor layer serving as a strained semiconductor layer formed on the first semiconductor layer; and
a third semiconductor layer serving as a cap layer formed on the second semiconductor layer.

2. The semiconductor wafer according to claim 1, wherein the lattice constant of the first semiconductor layer is greater than the lattice constant of the semiconductor substrate.

3. The semiconductor wafer according to claim 1, wherein the second semiconductor layer and the semiconductor substrate are formed of an identical material.

4. The semiconductor wafer according to claim 3, wherein the second semiconductor layer and the semiconductor substrate are formed of silicon.

5. The semiconductor wafer according to claim 1, wherein a lattice constant of the third semiconductor layer is different from a lattice constant of the second semiconductor layer.

6. The semiconductor wafer according to claim 1, wherein the semiconductor substrate is a Si substrate.

7. The semiconductor wafer according to claim 1, wherein the first semiconductor layer is a SiGe layer.

8. The semiconductor wafer according to claim 1, wherein the first semiconductor layer includes a first SiGe layer provided to a semiconductor substrate side and a second SiGe layer formed on the first SiGe layer, a Ge concentration of the first SiGe layer increasing as a distance from the semiconductor substrate increases, and a Ge concentration of the second SiGe layer being constant.

9. The semiconductor wafer according to claim 8, wherein the Ge concentration of the second SiGe layer is 30%.

10. The semiconductor wafer according to claim 1, wherein the second semiconductor layer is a strained Si layer.

11. The semiconductor wafer according to claim 1, wherein the third semiconductor layer is a SiGe layer.

12. The semiconductor wafer according to claim 11, wherein the Ge concentration of the SiGe layer is 5% or less.

13. The semiconductor wafer according to claim 11, wherein the third semiconductor layer is a Sb-doped Si layer.

14. The semiconductor wafer according to claim 1, wherein the third semiconductor layer has a film thickness of 5 to 30 nm.

15. A method of manufacturing a semiconductor device comprising:
forming a first semiconductor layer on the semiconductor substrate, the first semiconductor layer serving as a buffer layer, a lattice constant of the first semiconductor layer being different from a lattice constant of the semiconductor substrate;
forming a second semiconductor layer serving as a strained semiconductor layer on the first semiconductor layer;
re-growing the second semiconductor layer to compensate for a thickness of the second semiconductor layer, which has been decreased during a previous manufacturing process;
forming an insulating film on the second semiconductor; and
forming a semiconductor element on the insulating film.

16. The method of manufacturing a semiconductor device according to claim 15, wherein the second semiconductor layer is a Si layer.

17. The method of manufacturing a semiconductor device according to claim 15, wherein the re-growing of the second semiconductor layer is performed before forming the insulating film.

18. The method of manufacturing a semiconductor device according to claim 15, wherein the semiconductor element is a transistor, and the insulating film is a gate insulating film.

19. A method of manufacturing a semiconductor device comprising:
forming a first semiconductor layer on the semiconductor substrate, the first semiconductor layer serving as a buffer layer, and a lattice constant of the first semiconductor layer being different from a lattice constant of the semiconductor substrate;
forming a second semiconductor layer serving as a strained semiconductor layer on the first semiconductor layer;
forming a third semiconductor layer serving as a cap layer on the second semiconductor layer, removing at least part of the third semiconductor layer;
forming an insulating film on the second semiconductor; and
forming a semiconductor element on the insulating film.

20. The method of manufacturing a semiconductor device according to claim 19, wherein the semiconductor element is a transistor, and the insulating film is a gate insulating film.
